(19) United States
(12) Patent Application Publication
(10) Pub. No.: US 2026/0045444 A1
(43) Pub. Date: Feb. 12, 2026

(54) Charged Particle Beam Device

(71) Applicant: Hitachi High-Tech Corporation, Minato-ku, Tokyo (JP)

(72) Inventors: Yoshinori HIGASHI, Tokyo (JP); Makoto SATO, Tokyo (JP); Ayana MURAKI, Tokyo (JP); Satoshi TOMIMATSU, Tokyo (JP); Tatsuya ASAHATA, Tokyo (JP)

(21) Appl. No.: 19/150,080

(22) PCT Filed: Jan. 27, 2023
(86) PCT No.: PCT/JP2023/002583

§ 371 Date: Jul. 22, 2025

(51) Int. Cl. H01J 37/20; H01J 37/22; H01J 37/28

(52) U.S. Cl. CPC H01J 37/20; H01J 37/222; H01J 37/28; H01J 2237/335

(57) ABSTRACT

Provided is a charged particle beam device capable of removing a foreign matter adhering to a distal tip of a needle. The charged particle beam device includes: a charged particle beam irradiation optical system configured to radiate a charged particle beam; a sample stage configured to mount and move a sample; a sample piece transferring unit including a needle configured to hold and transfer a sample piece to be separated and extracted from the sample and a needle driving mechanism configured to drive the needle; a holder fixing base configured to hold a sample piece holder to which the sample piece is transferred; a machine learning model in which information including an image of the needle is learned; and a computer configured to control the charged particle beam irradiation optical system to process an object, based on determination of the machine learning model.

### DESCRIPTION

### Technical Field

The present disclosure relates to a charged particle beam device, and in particular, to a technique effectively applied to a charged particle beam device having a needle.

### Background Art

PTL 1 proposes a charged particle beam device that extracts a sample piece produced by irradiating a sample with an ion beam and transfers the sample piece to a sample holder for transmission electron microscope observation.

In the charged particle beam device, a needle is used to extract a sample piece processed by irradiation with an ion beam. A shape of a tip of a needle may be changed or a foreign matter may adhere to the tip of the needle due to bonding and cutting with the sample piece, and in this case, cleaning processing for shaping a tip shape of the needle is performed using an ion beam.

PTL 1 discloses a technique of creating a desired constant shape by recognizing a tip shape of a needle using an image processing technique, setting a rectangular processing frame in a region outside upper and lower edges of the needle, and performing ion beam processing.

### CITATION LIST

### Patent Literature

PTL 1: JP2020-139958A

### SUMMARY OF INVENTION

### Technical Problem

However, in the above-described cleaning processing, there is a case where a needle having an optimum shape for transferring the sample piece cannot be used due to a deposit remaining at a distal tip of the needle or deformation of the shape of the needle. PTL 2 does not disclose or suggest machine learning of deposits at a distal tip of a needle.

The present disclosure provides a charged particle beam device capable of providing a needle having a shape optimal for transferring a sample piece.

Other technical problems and novel features will become apparent from description of the present description and the accompanying drawings.

### Solution to Problem

An outline of a typical aspect according to the present disclosure will be briefly described below.

According to one embodiment, a charged particle beam device includes: a charged particle beam irradiation optical system configured to radiate a charged particle beam; a sample stage configured to mount and move a sample; a sample piece transferring unit including a needle configured to hold and transfer a sample piece to be separated and extracted from the sample and a needle driving mechanism configured to drive the needle; a holder fixing base configured to hold a sample piece holder to which the sample piece is transferred; a machine learning model in which information including an image of the needle is learned; and a computer configured to control the charged particle beam irradiation optical system to process an object, based on determination of the machine learning model.

### Advantageous Effects of Invention

According to a charged particle beam device of the above embodiment, it is possible to process a needle into a shape optimal for transferring a sample piece.

### BRIEF DESCRIPTION OF DRAWINGS

FIG. 1 is a diagram illustrating an example of a configuration of a charged particle beam device and an image processing computer according to an embodiment.

FIG. 2 is a diagram illustrating a configuration of the charged particle beam device according to the embodiment.

FIG. 3 is a plan view illustrating a sample piece according to the embodiment.

FIG. 4 is a plan view illustrating a sample piece holder according to the embodiment.

FIG. 5 is a side view illustrating the sample piece holder according to the embodiment.

FIG. 6 is a diagram illustrating an example of the configuration of the image processing computer according to the embodiment.

FIG. 7 is a diagram illustrating an example of an initial setting process according to the embodiment.

FIG. 8 is a top view illustrating a columnar portion according to the embodiment.

FIG. 9 is a side view illustrating the columnar portion according to the embodiment.

FIG. 10 is a diagram illustrating an example of learning images of the columnar portion according to the embodiment.

FIG. 11 is a diagram illustrating an example of a columnar portion in which a pillar according to the embodiment does not have a stepped structure.

FIG. 12 is a diagram illustrating an example of learning images of the columnar portion in which the pillar according to the embodiment does not have a stepped structure.

FIG. 13 is a diagram illustrating an example of a sample piece pickup process according to the embodiment.

FIG. 14 is a diagram illustrating an example of a moving process of a needle according to the embodiment.

FIG. 15 is a view illustrating an example of SEM image data including a tip of the needle according to the embodiment.

FIG. 16 is a view illustrating an example of SIM image data including the tip of the needle according to the embodiment.

FIG. 17 is a diagram illustrating an example of the tip of the needle according to the embodiment.

FIG. 18 is a diagram illustrating an example of learning images of the needle according to the embodiment.

FIG. 19 is a diagram illustrating an example of SIM image data including a sample piece according to the embodiment.

FIG. 20 is a diagram illustrating an example of learning images of the sample piece according to the embodiment.

FIG. 21 is a diagram illustrating a cutting processing position of a support portion of a sample and the sample piece in the SIM image data according to the embodiment.

FIG. 22 is a diagram illustrating an example of a sample piece mounting process according to the embodiment.

FIG. 23 is a diagram illustrating an example of a needle trimming process according to the embodiment.

FIG. 24 is a diagram illustrating an example of learning images of the needle according to the embodiment.

FIG. 25 is a diagram illustrating an example of learning images of a needle in which a thickness of a tip is changed by cleaning according to the embodiment.

FIG. 26 is a diagram illustrating an example of original images of a needle to which a foreign matter adheres according to the embodiment.

FIG. 27 is a diagram illustrating an example of teacher images showing a region of a foreign matter in the original image in FIG. 26 according to the embodiment.

FIG. 28 is a diagram illustrating an example of original images in which contrast, an angle, magnification, a position, and the like of the needle according to the embodiment are changed.

FIG. 29 is a diagram illustrating an example of one set of learning data of an original image in which a foreign matter adheres to a tip portion of a needle whose tip thickness has been changed by the cleaning and a teacher image thereof according to the embodiment.

FIG. 30 is a diagram illustrating an example of a learning model for needle cleaning necessity determination according to the embodiment.

FIG. 31 is a diagram illustrating an example of a processing frame according to a comparative example.

FIG. 32 is a diagram illustrating a problem of the processing frame according to the comparative example.

FIG. 33 is a diagram illustrating an example of a processing frame according to the embodiment.

FIG. 34 is a diagram illustrating setting examples of a processing frame according to the embodiment.

FIG. 35 is a diagram illustrating shaping of the needle according to the embodiment.

### DESCRIPTION OF EMBODIMENTS

Hereinafter, embodiments will be described with reference to the drawings. However, in the following description, the same components are denoted by the same reference signs, and repeated description thereof may be omitted. It should be noted that the drawings may be more schematically illustrated than actual aspects in order to clarify the description, but are merely examples and do not limit the interpretation of the present disclosure.

### Embodiments

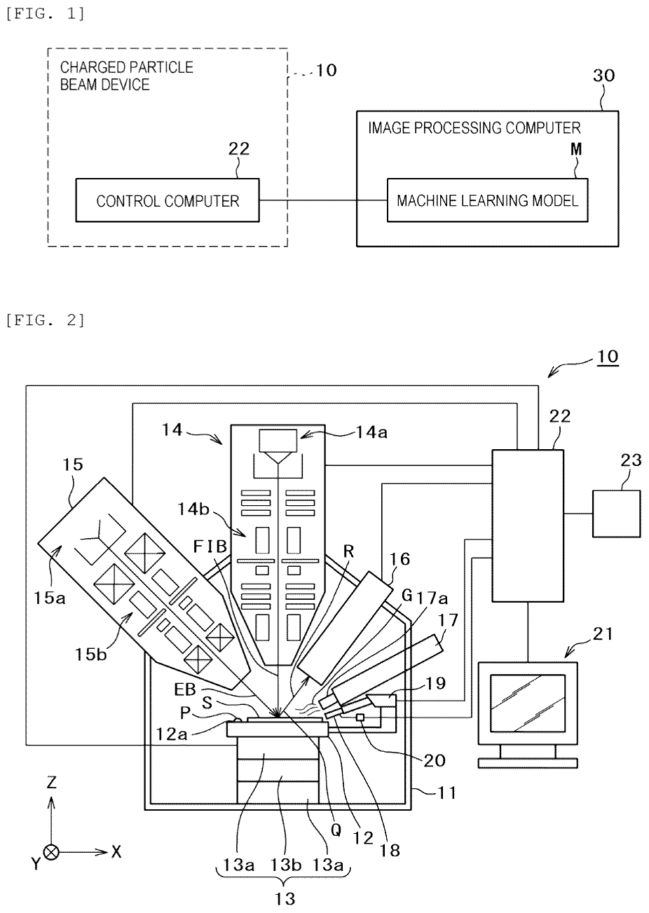

Hereinafter, an embodiment of the invention will be described in detail with reference to the drawings. FIG. 1 is a diagram illustrating an example of a configuration of a charged particle beam device 10 and an image processing computer 30 according to the present embodiment.

A control computer 22 provided in the charged particle beam device 10 acquires image data acquired by irradiation with a charged particle beam. The control computer 22 transmits and receives data to and from an image processing computer 30. The image processing computer 30 determines an object included in the image data received from the control computer 22, based on a machine learning model M. Based on a determination result of the image processing computer 30, the control computer 22 executes control of a position related to an object, removal of a foreign matter adhering to a tip of a needle, and the like.

The control computer 22 is an example of a computer that executes control of a position related to a second object based on a machine learning model in which first information including a first image of a first object is learned and second information including a second image acquired by irradiation with a charged particle beam. The image processing computer 30 may be provided in the charged particle beam device 10.

### (Overall Configuration of Charged Particle Beam Device)

Next, a configuration of the charged particle beam device 10 will be described with reference to FIG. 2. FIG. 2 is a diagram illustrating an example of the configuration of the charged particle beam device 10 according to the embodiment.

The charged particle beam device 10 includes a sample chamber 11, a sample stage 12, a stage driving mechanism 13, a focused ion beam irradiation optical system (also referred to as a charged particle beam irradiation optical system) 14, an electron beam irradiation optical system 15, a detector 16, a gas supply unit 17, a needle 18, a needle driving mechanism 19, an absorption current detector 20, a display device 21, a control computer 22, and an input device 23.

The inside of the sample chamber 11 is maintained in a vacuum state. The sample stage 12 fixes a sample S and a sample piece holder P inside the sample chamber 11. Here, the sample stage 12 includes a holder fixing base 12a that holds the sample piece holder P. The holder fixing base 12a may have a structure on which a plurality of sample piece holders P can be mounted.

The stage driving mechanism 13 drives the sample stage 12. Here, the stage driving mechanism 13 is accommodated inside the sample chamber 11 in a state of being connected to the sample stage 12, and allows the sample stage 12 to be displaced relative to a predetermined axis according to a control signal output from the control computer 22. The stage driving mechanism 13 includes moving mechanisms 13a that move the sample stage 12 parallel to at least an X-axis and a Y-axis parallel to a horizontal plane and orthogonal to each other and a Z-axis in a vertical direction orthogonal to the X-axis and the Y-axis. The stage driving mechanism 13 includes an inclination mechanism 13b that inclines the sample stage 12 around the X-axis or the Y-axis, and a rotation mechanism 13c that rotates the sample stage 12 around the Z-axis.

The focused ion beam irradiation optical system 14 irradiates an irradiation target in a predetermined irradiation region (that is, a scanning range) inside the sample chamber 11 with a focused ion beam (FIB). Here, the focused ion beam irradiation optical system 14 irradiates an irradiation target such as the sample S, a sample piece Q mounted on the sample stage 12, and the needle 18 present in the irradiation region with a focused ion beam from above to below in the vertical direction.

### The Focused Ion Beam Irradiation Optical System 14

includes an ion source 14a that generates ions and an ion optical system 14b that focuses and deflects the ions extracted from the ion source 14a. The ion source 14a and the ion optical system 14b are controlled according to a control signal output from the control computer 22, and an irradiation position, an irradiation condition, and the like of a focused ion beam are controlled by the control computer 22.

The electron beam irradiation optical system 15 irradiates an irradiation target in a predetermined irradiation region inside the sample chamber 11 with an electron beam (EB). Here, the electron beam irradiation optical system 15 may irradiate an irradiation target such as the sample S fixed to the sample stage 12, the sample piece Q, and the needle 18 present in an irradiation region with an electron beam from above to below in an inclination direction inclined by a predetermined angle (for example, 60°) relative to the vertical direction.

The electron beam irradiation optical system 15 includes an electron source 15a that generates electrons and an electron optical system 15b that focuses and deflects the electrons emitted from the electron source 15a. The electron source 15a and the electron optical system 15b are controlled according to a control signal output from the control computer 22, and an irradiation position, an irradiation condition, and the like of an electron beam are controlled by the control computer 22.

The arrangement of the electron beam irradiation optical system 15 and the focused ion beam irradiation optical system 14 may be switched, and the electron beam irradiation optical system 15 may be disposed in the vertical direction and the focused ion beam irradiation optical system 14 may be disposed in an inclination direction inclined by a predetermined angle in the vertical direction.

The detector 16 detects secondary charged particles (secondary electrons, secondary ions) R generated from an irradiation target by irradiation with a focused ion beam or an electron beam. The gas supply unit 17 supplies a gas G to a surface of the irradiation target. The needle 18 takes out a minute sample piece Q from the sample S fixed to the sample stage 12, holds the sample piece Q, and transfers the sample piece Q to the sample piece holder P. The needle driving mechanism 19 drives the needle 18 to transfer the sample piece Q. Hereinafter, the needle 18 and the needle driving mechanism 19 may be collectively referred to as a sample piece transferring unit.

The absorption current detector 20 detects an inflow current (also referred to as an absorption current) of the charged particle beam flowing into the needle 18, and outputs the detected result to the control computer 22 as an inflow current signal.

The control computer 22 controls at least the stage driving mechanism 13, the focused ion beam irradiation optical system 14, the electron beam irradiation optical system 15, the gas supply unit 17, and the needle driving mechanism 19. The control computer 22 is disposed outside the sample chamber 11, and is connected to the display device 21 and the input device 23 such as a mouse or a keyboard that outputs a signal according to an input operation of an operator. The control computer 22 integrally controls an operation of the charged particle beam device 10 according to a signal output from the input device 23, a signal generated by a preset automatic operation control process, or the like.

As described above, the control computer 22 executes control of the position related to the object based on the determination result of the image processing computer 30. The control computer 22 includes a communication interface for communicating with the image processing computer 30.

The control computer 22 images the inflow current signal output from the absorption current detector 20 as absorption current image data. Here, the control computer 22 converts a detection amount of the secondary charged particles R detected by the detector 16 while scanning the irradiation position into a luminance signal associated with an irradiation position of the charged particle beam, and generates absorption current image data indicating a shape of an irradiation target by the two-dimensional position distribution of the detection amount of the secondary charged particles R. In an absorption current image mode, the control computer 22 detects an absorption current flowing through the needle 18 while scanning the irradiation position of the charged particle beam, thereby generating absorption current image data indicating a shape of the needle 18 by the two-dimensional position distribution of the absorption current (absorption current image). Further, the control computer 22 causes the display device 21 to display a screen for executing operations such as enlargement, reduction, movement, and rotation of each image data together with each generated image data. The computer 22 causes the display device 21 to display a screen for performing various settings such as mode selection and processing setting in automatic sequence control.

The display device 21 displays image data or the like based on the secondary charged particles R detected by the detector 16.

In addition, the image processing computer 30 captures the image data generated by the control computer 22, specifies a region of a foreign matter adhering to the needle 18, and transmits coordinate information of the region to the control computer 22. The control computer 22 sets a processing frame that defines an operation region of the charged particle beam according to the coordinates of the region of the foreign matter received from the image processing computer 30.

The charged particle beam device 10 irradiates a surface of an irradiation target with a focused ion beam while scanning the surface, thereby executing imaging of the irradiation target, various processes (excavation, trimming, and the like) by sputtering, formation of a deposited film, and the like.

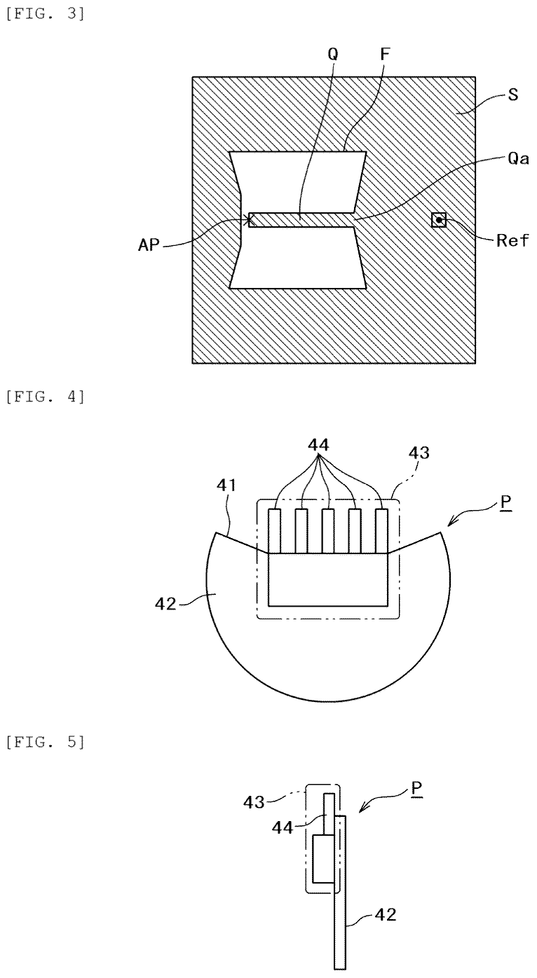

FIG. 3 is a plan view illustrating the sample piece Q before being extracted from the sample S, which is formed by irradiating a surface (hatched portion) of the sample S with a focused ion beam in the charged particle beam device 10 according to the embodiment. Reference F indicates a processing frame by the focused ion beam, that is, a scanning range of the focused ion beam, and an inner side (white portion) thereof indicates a processing region H which is sputtered and excavated by the radiation of the focused ion beam. The reference mark Ref is a reference point indicating a position where the sample piece Q is formed (left without being excavated). A deposited film is used to know an approximate position of the sample piece Q, and a fine hole is used for precise alignment. In the sample S, the sample piece Q is subjected to the etching processing so that peripheral portions on a side portion side and a bottom portion side are cut and removed while leaving a support portion Qa connected to the sample S, and is cantilevered on the sample S by the support portion Qa.

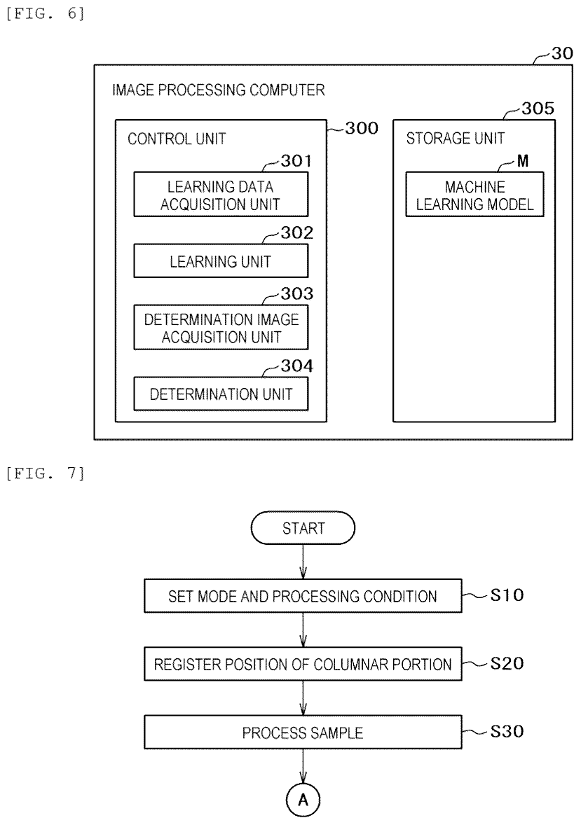

Next, the sample piece holder P will be described with reference to FIGS. 4 and 5.

FIG. 4 is a plan view of the sample piece holder P, and FIG. 5 is a side view thereof. The sample piece holder P includes a substantially semicircular plate-shaped base portion 42 having a cutout portion 41, and a sample stage 43 fixed to the cutout portion 41. The base portion 42 is formed of, for example, a circular plate-shaped metal. The sample stage 43 has a comb shape, and includes a plurality of columnar portions (hereinafter, also referred to as pillars) 44 which are spaced apart and protrude and to which the sample piece Q is transferred.

### (Image Processing Computer)

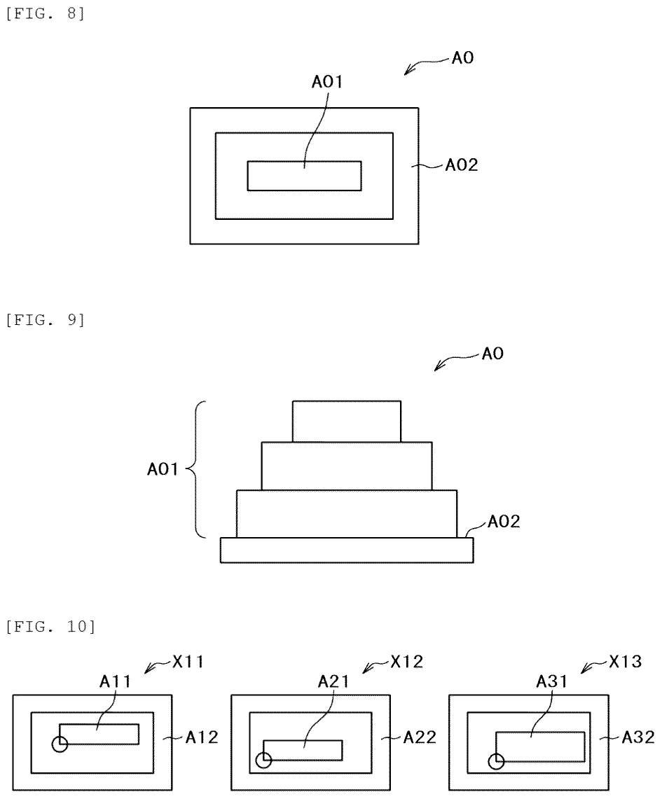

Next, the image processing computer 30 will be described with reference to FIG. 6. FIG. 6 is a diagram illustrating an example of a configuration of the image processing computer 30 according to the present embodiment.

The image processing computer 30 includes a control unit 300 and a storage unit 305.

The control unit 300 includes a learning data acquisition unit 301, a learning unit 302, a determination image acquisition unit 303, and a determination unit 304.

The learning data acquisition unit 301 acquires learning data. The learning data is information used to learn of machine learning. The learning data is a set of a learning image and information indicating a position of an object in the learning image. Examples of the object in the learning image include a sample piece, a needle, a foreign matter adhering to a tip of the needle, and a columnar portion provided in a sample piece holder. Here, a type of an object in the learning image and a type of an object in a determination image are the same. For example, when the type of the object in the learning image is a sample piece, a needle, or foreign matters adhering to the tip of the needle or a columnar portion, the type of the object in the determination image is a sample piece, a needle, or a foreign matter adhering to the tip of the needle or a columnar portion.

Here, in the present embodiment, an SIM image or an SEM image obtained in advance by irradiating an object with a charged particle beam is used as the learning image. The object is irradiated with the charged particle beam from a predetermined direction. In the charged particle beam device 10, since a direction of a column of a charged particle beam irradiation system is fixed, a direction in which the object is irradiated with the charged particle beam is determined in advance.

The information indicating a position of the object in the learning image is, for example, coordinates indicating the position of the object in the learning image. The coordinates indicating the position in the learning image are, for example, two-dimensional orthogonal coordinates or polar coordinates.

The learning image includes both the SIM image and the SEM image of the object. The learning images are both a SIM image of the object viewed from an inclination direction inclined by a predetermined angle relative to the vertical direction of the sample stage 12 and a SEM image of the object viewed from the vertical direction of the sample stage 12. That is, the learning image includes an image of the object viewed from a first direction relative to the sample stage 12 and an image of the object viewed from a second direction. The second direction is a direction different from the first direction relative to the sample stage 12.

The learning unit 302 executes machine learning based on the learning data acquired by the learning data acquisition unit 301. The learning unit 302 stores the learning result as the machine learning model M in the storage unit 305. The learning unit 302 executes machine learning for each type of object in the learning image included in the learning data. Therefore, the machine learning model M is generated for each type of object of the learning image included in the learning data. The machine learning model M is an example of a model of machine learning in which first information including the first image of the first object is learned. In the following description, an object captured or drawn in an image may be referred to as an object of the image.

Here, the machine learning executed by the learning unit 302 is, for example, deep learning using a convolutional neural network (CNN) or the like. In this case, the machine learning model M is a multilayer neural network in which a weight between nodes is changed according to the correspondence between the learning image and the position of the object in the learning image. The multilayer neural network includes an input layer having nodes corresponding to respective pixels of an image and an output layer having nodes corresponding to respective positions in the image, and when a luminance value of each pixel of a SIM image or a SEM image is input to the input layer, a set of values indicating a position in the image is output from the output layer.

The determination image acquisition unit 303 acquires a determination image. The determination image is a SIM image or a SEM image output from the control computer 22. The determination image includes an image of the object described above. The object included in the determination image includes an object related to irradiation with the charged particle beam such as the sample piece Q, the needle 18 after use, and a foreign matter adhering to the tip of the needle 18.

The determination images are both a SIM image of the object viewed from an inclination direction inclined by a predetermined angle relative to the vertical direction of the sample stage 12 and a SEM image of the object viewed from the vertical direction of the sample stage 12. That is, the determination image includes an image of the object viewed from the first direction and an image of the object viewed from the second direction. Here, the first direction is a direction relative to the sample stage 12, and the second direction is a direction different from the first direction relative to the sample stage 12.

The determination unit 304 determines a position of an object included in the determination image acquired by the determination image acquisition unit 303, based on the machine learning model M in which the learning is executed by the learning unit 302. Here, the position of the object included in the determination image includes, for example, a pickup position of a sample piece in a SIM image or a SEM image, a position of a tip of a needle in the SIM image or the SEM image, a position of a foreign matter at a tip of the needle 18 in the SIM image or the SEM image, and a position of the columnar portion 44 in the SIM image or the SEM image. As an example, the determination unit 304 determines coordinates of an object in the determination image as a position of the object included in the determination image. Here, the needle 18 may have a conical shape having a sharpened tip shape, a sharpened cylindrical shape, or a sharpened prism shape. A learning model of a tip shape of the needle 18 may be selectively used according to the tip shape of the needle 18. Accordingly, the needle 18 having various tip shapes can be used in the charged particle beam device 10. As the learning model, a learning model for a shape of the needle 18 whose tip shape is changed depending on use is also prepared, and the learning model can be selectively used according to the use situation of the needle 18. Here, the selective use means that the learning model is selectively used and changed according to a change in the tip shape depending on use. Accordingly, one needle 18 can be continuously used in one charged particle beam device 10 for a long time. Therefore, since the frequency of replacement of the needle 18 can be reduced, the number of times of maintenance of the charged particle beam device 10 can be reduced. Accordingly, an operating time of the charged particle beam device 10 can be increased.

The image processing computer 30 may acquire the learned machine learning model from, for example, an external database. In this case, the control unit 300 may not include the learning data acquisition unit 301 or the learning unit 302.

Hereinafter, an operation of automatic micro-sampling (MS) performed by the control computer 22, that is, an operation of automatically transferring, to the sample piece holder P, the sample piece Q formed by processing the sample S with a charged particle beam (focused ion beam) will be roughly divided into an initial setting process, a sample piece pickup process, a sample piece mounting process, and a needle trimming process and be sequentially described.

### (Initial Setting Process)

FIG. 7 is a diagram illustrating an example of an initial setting process according to the present embodiment.

Step S10: The control computer 22 sets a mode and a processing condition. The setting of the mode is a setting such as the presence or absence of an attitude control mode, which will be described later, in accordance with an input by the operator at the start of the automatic sequence. The setting of the processing condition is setting of a processing position, a dimension, the number of sample pieces Q, and the like.

Step S20: The control computer 22 registers the position of the columnar portion 44. Here, the control computer 22 transmits the SIM image or the SEM image including the columnar portion 44 as the object to the image processing computer 30.

In the present embodiment, the absorption current image data including the object is a set of the SIM image of the object and the SEM image of the object. That is, the SIM image or the SEM image including the object is a set of the SIM image when the object is viewed from an inclination direction inclined by a predetermined angle relative to the vertical direction of the sample stage 12 and the SEM image when the object is viewed from the vertical direction of the sample stage 12.

The determination image acquisition unit 303 acquires a SIM image or a SEM image as a determination image from the image processing computer 30. The determination unit 304 determines a position of the columnar portion 44 included in the determination image acquired by the determination image acquisition unit 303 based on the machine learning model M. The determination unit outputs position information indicating the determined position of the columnar portion 44 to the control computer 22.

Here, the determination unit 304 determines two-dimensional coordinates of a position of an object on the sample stage 12 from a SIM image of the object viewed from an inclination direction inclined by a predetermined angle relative to the vertical direction of the sample stage 12. On the other hand, the determination unit 304 determines two-dimensional coordinates of a position of an object on a plane perpendicular to an inclination direction from a SEM image of the object viewed from the inclination direction inclined by a predetermined angle relative to the vertical direction of the sample stage 12. The determination unit 304 determines a position of an object as values of three-dimensional coordinates based on the determined two-dimensional coordinates on the sample stage 12 and two-dimensional coordinates on the plane perpendicular to the inclination direction.

The determination unit 304 uses direction information, which is information on a direction in which the electron beam irradiation optical system and the focused ion beam irradiation optical system 14 are disposed in the charged particle beam device 10 and an angle between the electron beam irradiation optical system 15 and the focused ion beam irradiation optical system 14, for calculating values of the three-dimensional coordinates. The determination unit 304 stores and reads the direction information in the storage unit 305 in advance or acquires the direction information from the control computer 22. Here, in step S20, the object is the columnar portion 44. In the following processes, the determination unit 304 determines the position of the object in the same manner.

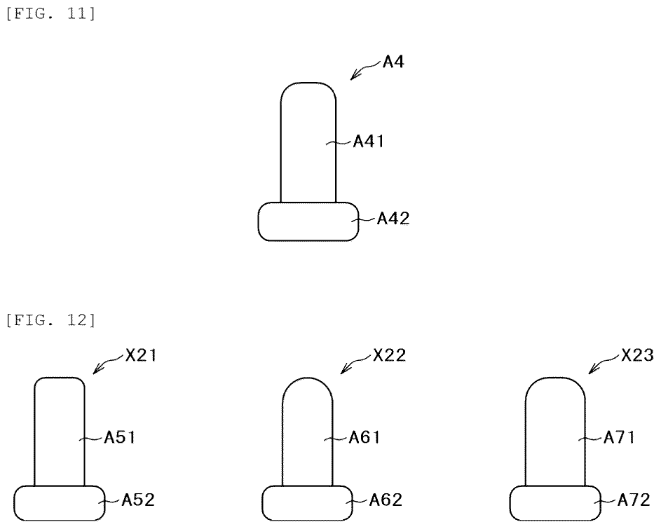

Here, the columnar portion 44 and learning images of the columnar portion 44 used to generate the machine learning model M will be described with reference to FIGS. 8 to 12. FIGS. 8 and 9 are diagrams illustrating an example of the columnar portion 44 according to the present embodiment. A columnar portion A0 illustrated in FIGS. 8 and 9 is an example of a design structure of the columnar portion 44. Here, FIG. 8 is a top view of the columnar portion A0, and FIG. 9 is a side view of the columnar portion A0. The columnar portion A0 has a structure in which a pillar A01 having a stepped structure is bonded to a base portion A02.

FIG. 10 is a diagram illustrating an example of learning images of the columnar portion 44 according to the present embodiment. A learning image X11, a learning image X12, and a learning image X13 are used to learn positions of the columnar portion 44. In the learning image X11, the learning image X12, and the learning image X13, information indicating the positions of the columnar portion is indicated as a circle. In the learning image X11, the learning image X12, and the learning image X13, shapes of a pillar All, a pillar A21, and a pillar 31 are different from each other. On the other hand, in the learning image X11, the learning image X12, and the learning image X13, a base portion A12, a base portion A22, and a base portion A32 have the same shape.

As an example, the learning image X11, the learning image X12, and the learning image X13 are learning images for determining the position of the columnar portion 44 included in the SIM image or the SEM image when the columnar portion 44 is viewed from a horizontal direction of the sample stage 12. In FIG. 2, the focused ion beam irradiation optical system 14 and the electron beam irradiation optical system 15 do not face the sample stage 12 from the horizontal direction of the sample stage 12, but any one of the focused ion beam irradiation optical system 14 or the electron beam irradiation optical system 15 may face the sample stage 12 from the horizontal direction, and the learning image X11, the learning image X12, and the learning image X13 are learning images for determining the position of the columnar portion 44 in that case.

FIG. 11 is a diagram illustrating an example of the columnar portion 44 in which a pillar according to the embodiment does not have a stepped structure. The columnar portion A4 illustrated in FIG. 11 is a side view of an example of a design structure of the columnar portion 44 in which the pillar does not have a stepped structure.

FIG. 12 is a diagram illustrating an example of a learning image of the columnar portion 44 in which the pillar according to the present embodiment does not have a stepped structure. As an example, a learning image X21, a learning image X22, and a learning image X23 are learning images for determining the position of the columnar portion 44 included in the SEM image when the columnar portion 44 is viewed from the vertical direction of the sample stage 12.

In the learning image X21, the learning image X22, and the learning image X23, shapes of a pillar A51, a pillar A61, and a pillar 71 are different from each other. On the other hand, in the learning image X21, the learning image X22, and the learning image X23, a base portion A52, a base portion A62, and a base portion A72 have the same shape.

Since the machine learning model M is generated based on machine learning using a learning image including a base portion of the columnar portion 44, in the machine learning model M, for example, a shape of the base portion is learned as feature data. Therefore, in the charged particle beam device 10, even when the shape of the pillar is different, the accuracy of the determination of the columnar portion is improved. is preferable that the object of the learning image includes portions having the same shape among the objects of a plurality of learning images.

Returning to FIG. 7, the description of the initial setting process will be continued.

The control computer 22 registers a position of the columnar portion 44 based on the position information indicating the position of the columnar portion 44 determined by the image processing computer 30.

The learning image of the columnar portion 44 preferably includes images of columnar portions located at both ends of the sample stage 43 among the columnar portions 44. Based on the machine learning model M generated using the learning data including the learning image, the image processing computer 30 detects columnar portions at both ends of the sample stage 43 of the columnar portions 44 separately from the columnar portions other than both ends. The control computer 22 may calculate the inclination of the sample piece holder P from the detected positions of the columnar portions at both ends. The control computer 22 may correct a value of the coordinate of the position of the object based on the calculated inclination.

Step S30: The control computer 22 controls the focused ion beam irradiation optical system 14 to process the sample S.

### (Sample Piece Pickup Process)

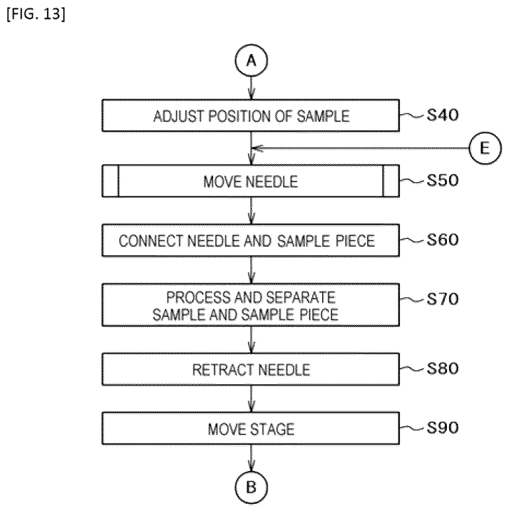

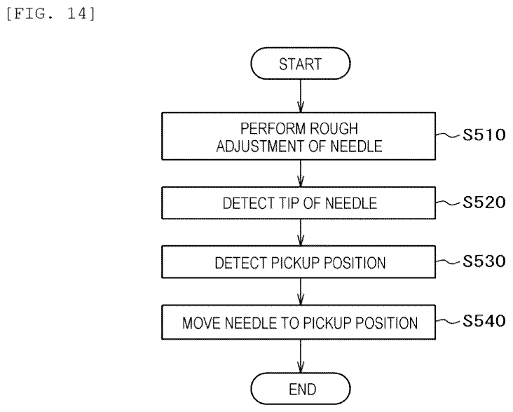

FIG. 13 is a diagram illustrating an example of a sample piece pickup process according to the present embodiment. Here, the pickup refers to separating and extracting the sample piece Q from the sample S by processing with a focused ion beam or a needle.

Step S40: The control computer 22 adjusts a position of the sample. Here, the control computer 22 moves the sample stage 12 by the stage driving mechanism 13 in order to put the target sample piece Q into the field of view of the charged particle beam. Here, the control computer 22 uses a relative positional relation between the reference mark Ref and the sample piece Q. The control computer 22 aligns the sample piece Q after the movement of the sample stage 12.

Step S50: The control computer 22 moves the needle 18.

Here, a process of moving the needle 18 performed by the control computer 22 will be described with reference to FIG. 14. FIG. 14 is a diagram illustrating an example of a moving process of the needle 18 according to the present embodiment. Step S510 to step 540 in FIG. 14 correspond to step S50 in FIG. 13.

Step S510: The control computer 22 performs needle movement (rough adjustment) of moving the needle 18 by the needle driving mechanism 19.

Step S520: The control computer 22 detects a tip of the needle 18. Here, the control computer 22 transmits the absorption current image data including the needle 18 as the object to the image processing computer 30.

The determination image acquisition unit 303 acquires a SIM image and a SEM image as a determination image from the image processing computer 30. The determination unit 304 determines a position of the needle 18: included in the determination image acquired by the determination image acquisition unit 303 as the position of the object based on the machine learning model M. The determination unit 304 outputs position information indicating the determined position of the needle 18 to the control computer 22.

Next, the control computer 22 performs needle movement (fine adjustment) of moving the needle 18 by the needle driving mechanism 19 based on the position information indicating the position of the needle 18 determined by the image processing computer 30.

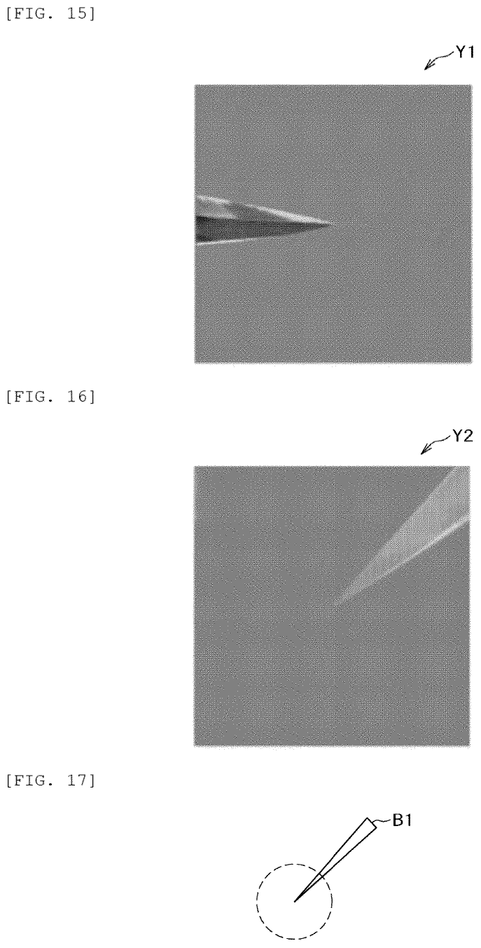

Here, the needle 18 and learning images of the needle 18 used to generate the machine learning model M will be described with reference to FIGS. 15 to 18. FIG. 15 is a view illustrating an example of SEM image data including the tip of the needle 18 according to the present embodiment. FIG. 16 is a diagram illustrating an example of SIM image data including the tip of the needle 18 according to the present embodiment.

FIG. 17 is a diagram illustrating an example of the tip of the needle 18 according to the present embodiment. FIG. 17 illustrates, as an example of the needle 18, a needle B1 when viewed from an inclination direction inclined by a predetermined angle relative to the vertical direction of the sample stage 12.

FIG. 18 is a diagram illustrating an example of learning images of the needle 18 according to the present embodiment. A learning image Y31, a learning image Y32, and a learning image Y33 are used to learn the position of the tip of the needle 18. In the learning image Y31, the learning image Y32, and the learning image Y33, information indicating the position of the tip of the needle 18 is indicated as a circle. The learning image Y31, the learning image Y32, and the learning image Y33 have different thicknesses of the tip of the needle. On the other hand, the learning image Y31, the learning image Y32, and the learning image Y33 have the same tip shape of the needle.

Regarding an actual thickness of the tip of the needle 18, the thickness is changed by cleaning. £ Since the machine learning model M is generated based on machine learning using a learning image including the tip of the needle 18, in the machine learning model M, for example, a tip shape of the needle is learned as feature data. Therefore, in the charged particle beam device 10, even when the thickness of the tip of the needle is different, the accuracy of the determination of the tip of the needle is improved.

Returning to FIG. 14, the description of the moving processing of the needle 18 will be continued.

Step S530: The control computer 22 detects a pickup position of the sample piece Q. Here, the control computer 22 transmits the SIM image or the SEM image including the sample piece Q as the object to the image processing computer 30.

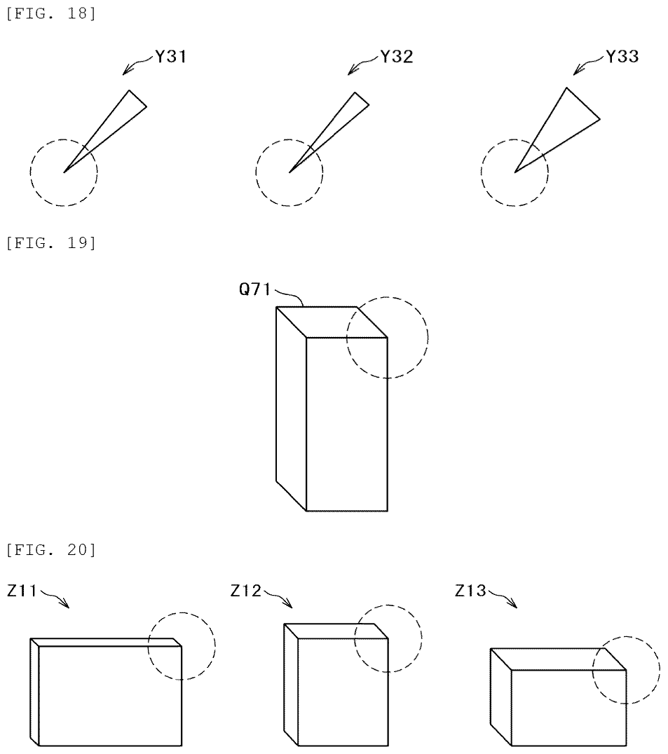

Here, the sample piece Q and learning images of the sample piece Q used to generate the machine learning model M will be described with reference to FIGS. 19 and 20.

FIG. 19 is a diagram illustrating an example of SIM image data including the sample piece Q according to the present embodiment. In FIG. 19, as an example of the sample piece Q, a sample piece Q71 is illustrated together with a circle indicating the pickup position.

FIG. 20 is a diagram illustrating an example of learning images of the sample piece Q according to the present embodiment. A learning image Z11, a learning image Z12, and a learning image Z13 are used to learn a position of a tip of the sample piece Q. In the learning image Z11, the learning image Z12, and the learning image Z13, information indicating a pickup position of the sample piece Q is indicated as a circle. The learning image Z11, the learning image Z12, and the learning image Z13 are different in a size and a shape of a surface of the sample piece. On the other hand, the learning image Z11, the learning image Z12, and the learning image Z13 have the same shape at a pickup position of the sample piece.

An actual shape of a surface of the sample piece is different for each individual. Since the machine learning model M is generated based on machine learning using a learning image including the pickup position of the sample piece Q, in the machine learning model M, for example, a shape at the pickup position of the sample piece Q is learned as feature data. Therefore, in the charged particle beam device 10, even when the shape of the surface of the sample piece is different, the accuracy of the determination of the pickup position of the sample piece Q is improved.

Returning to FIG. 14, the description of the moving process of the needle 18 will be continued.

Step S540: The control computer 22 moves the needle 18 to the detected pickup position.

Thus, the control computer 22 ends the moving process of the needle 18.

Returning to FIG. 13, the description of the sample piece pickup process will be continued.

Step S60: The control computer 22 connects the needle 18 and the sample piece Q. Here, the control computer 22 performs connection using a deposited film.

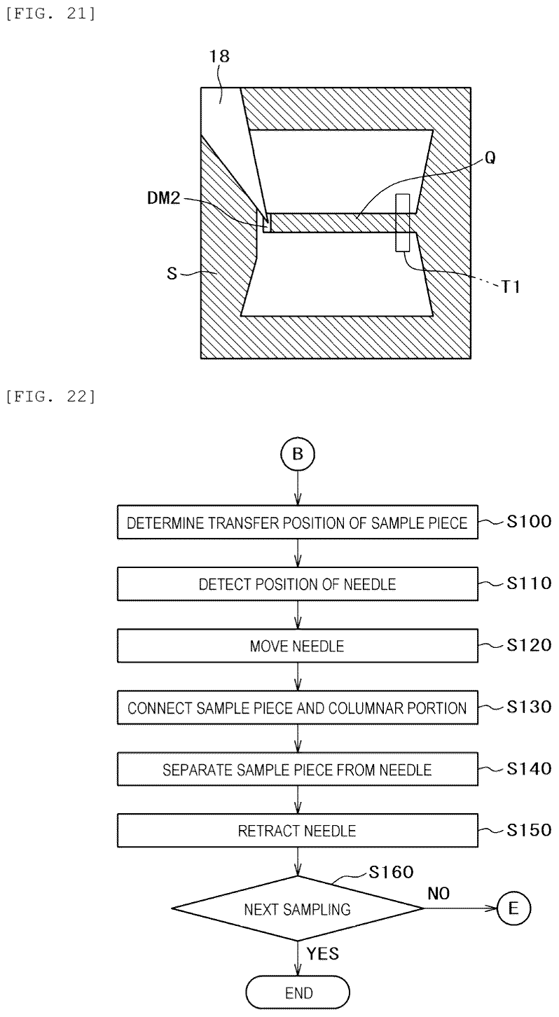

Step S70: The control computer 22 processes and separates the sample S and the sample piece Q. Here, FIG. 21 illustrates a state of processing and separation, and is a diagram illustrating the sample S and a cutting processing position T1 of the support portion Qa of the sample piece Q in the SIM image data according to the embodiment of the invention.

In the present embodiment, the sample piece pickup process and the sample piece mounting process may be performed on a sample piece Q0 that has been separately manufactured and processed in advance. In this case, after the position adjustment of the sample piece transferring unit (needle 18) and the sample piece Q0 is performed by designating and inputting the pickup position of the sample piece Q0 to the control computer 22, the cutting processing position T1 in FIG. 21 may be determined by machine learning. In the machine learning in this case, as the first image, an image indicating a position (cutting processing position) at which the sample piece transferring unit is caused to approach a sample piece in the sample extraction process of extracting a sample piece is used.

In this case, even if processing size shape information indicating a processing size and shape of the sample piece Q0 is not input to the control computer 22, the sample piece Q0 can be extracted and separated. After the sample piece Q0 is extracted, the subsequent sample piece mounting process may be performed in the same manner.

Step S80: The control computer 22 retracts the needle 18. Here, the control computer 22 detects the position of the tip of the needle 18 and moves and retracts the needle 18 in the same manner as the moving processing of the needle 18 in step S50.

Step S90: The control computer 22 moves the sample stage 12. Here, the control computer 22 moves the sample stage 12 by the stage driving mechanism 13 so that the specific columnar portion 44 registered in step S20 described above enters an observation visual field region by the charged particle beam.

### (Sample Piece Mounting Process)

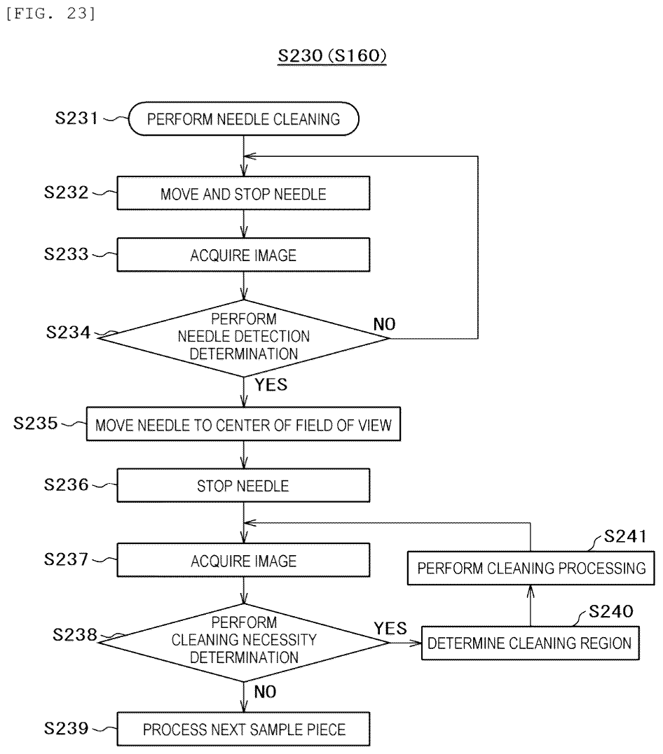

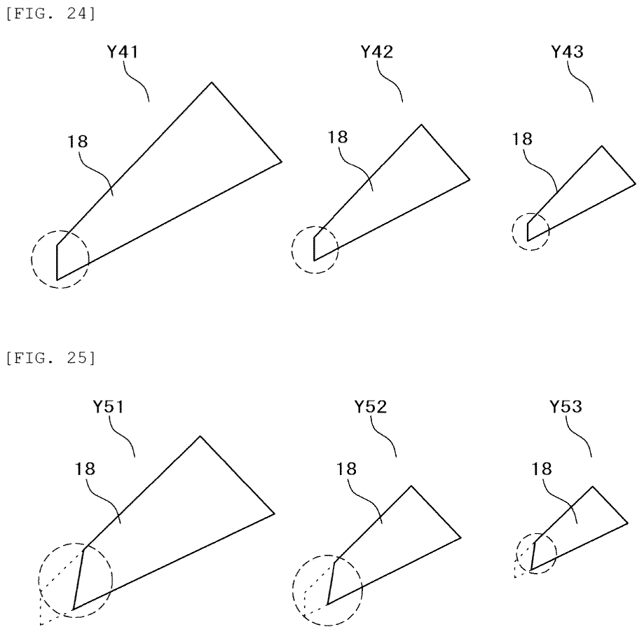

FIG. 22 is a diagram illustrating an example of a sample piece mounting process according to the present embodiment. Here, the sample piece mounting process is a process of transferring the extracted sample piece Q to the sample piece holder P.

Step S100: The control computer 22 determines a transfer position of the sample piece Q. Here, the control computer 22 determines, as the transfer position, the specific columnar portion 44 registered in step S20 described above.

Step S110: The control computer 22 detects the position of the needle 18. Here, the control computer 22 detects a position of the tip of the needle 18 in the same manner as in step S520 described above.

Step S120: The control computer 22 moves the needle 18. Here, the control computer 22 moves, by the needle driving mechanism 19, the needle 18 to the transfer position of the sample piece Q determined in step S100. The control computer 22 stops the needle 18 with a predetermined gap between the columnar portion 44 and the sample piece Q.

Step S130: The control computer 22 connects the columnar portion 44 and the sample piece Q connected to the needle 18.

Step S140: The control computer 22 separates the needle 18 from the sample piece Q. Here, the control computer 22 performs separation by cutting a deposited film DM2 that connects the needle 18 and the sample piece Q.

Step S150: The control computer 22 retracts the needle 18. Here, the control computer 22 moves the needle 18 away from the sample piece Q by a predetermined distance by the needle driving mechanism 19.

Step S160: The control computer 22 determines whether to perform the next sampling. Here, executing the next sampling means continuing the sampling from different places of the same sample S. Since the setting of the number to be sampled is registered in advance in step S10, the control computer 22 checks the data and determines whether to perform the next sampling.

When it is determined that the next sampling is to be performed (No), the control computer 22 performs a needle trimming process S230 illustrated in FIG. 23, then proceeds to step S50, and continues the subsequent steps as described above to perform a sampling operation. In this example, step S160 includes the needle trimming process S230. The needle trimming process S230 may be performed between step S160 and step S50.

On the other hand, when it is determined that the next sampling is not performed (Yes), the control computer 22 ends the series of flows of the automatic MS.

Next, the needle trimming process (step S230) will be described with reference to FIG. 23. FIG. 23 is a diagram illustrating an example of the needle trimming process according to the embodiment.

### (Step S230: Needle Trimming Process)

The control computer 22 performs the needle trimming process S230.

Step S231: The control computer 22 performs needle cleaning by trimming the needle 18 after sampling in the automatic sample sampling, that is, after separating, from the needle 18, the sample piece Q separated and extracted from the sample S by the needle 18. Accordingly, the control computer 22 can repeatedly use the needle 18 when separating and extracting the sample piece Q from the sample S. The control computer 22 removes deposits such as the deposited film DM2 and the residue of the sample piece adhering to the needle 18 by etching processing using a focused ion beam. The deposits such as the deposited film DM2 or the residue of the sample piece adhering to the needle 18 can be rephrased as foreign matter.

Step S232: The control computer 22 moves the needle 18 and the stage 13 to a place where there is no structure on the background of the needle 18 and stops the needle 18 and the stage 13.

Step S233: The control computer 22 acquires image data including the needle 18 by irradiation with the focused ion beam. The acquired image including the needle 18 is transmitted to the image processing computer 30. The determination image acquisition unit 303 acquires an image from the image processing computer 30 as a determination image.

Step S234: The determination unit 304 performs detection determination on the tip of the needle 18, included in the determination image acquired by the determination image acquisition unit 303, based on the machine learning model M. When it is determined that the tip of the needle 18 is detected (Yes), the determination unit 304 outputs position information indicating the determined position of the needle 18 to the control computer 22, and the process proceeds to step S235. When it is determined that the tip of the needle 18 is not detected (No), the process proceeds to step S232, and the subsequent steps are performed as described above.

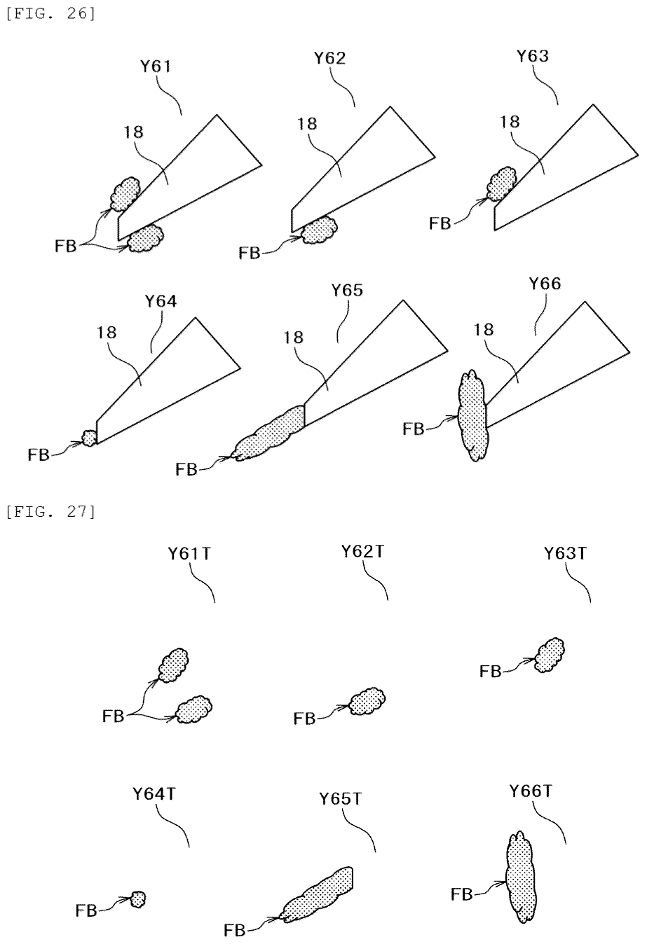

Here, an example of learning images of the needle 18 used to generate the machine learning model M will be described with reference to FIGS. 24 and 25. The learning images Y31 to Y33 illustrated in FIG. 18 described above can also be used.

FIG. 24 is a diagram illustrating an example of learning images of a needle according to the present embodiment. A learning image Y41, a learning image Y42, and a learning image Y43 are used to learn the position of the tip of the needle 18. In the learning image Y41, the learning image Y42, and the learning image Y43, information indicating the position of the tip of the needle 18 is indicated as a circle. The learning image Y41, the learning image Y42, and the learning image Y43 have different thicknesses of the tip of the needle. On the other hand, the learning image Y41, the learning image Y42, and the learning image Y43 have the same tip shape of the needle.

Regarding the actual thickness of the tip of the needle 18, the thickness of the tip is changed by cleaning. FIG. 25 is a diagram illustrating an example of learning images of a needle in which a thickness of a tip is changed by cleaning according to the present embodiment. A learning image Y51, a learning image Y52, and a learning image Y53 are examples of learning images of the needle 18 in which a thickness of a tip is changed by cleaning, and are used to learn the position of the tip of the needle 18. In the learning image Y51, the learning image Y52, and the learning image Y53, information indicating the position of the tip of the needle 18 is indicated as a circle. The learning image Y51, the learning image Y52, and the learning image Y53 show a case where the thickness of the tip of the needle indicated by the learning image Y41, the learning image Y42, and the learning image Y43 is changed by cleaning. The tip of the needle 18 may become thick even when the needle 18 is cut by mistake near the root during use. The learning image Y51, the learning image Y52, and the learning image Y53 may be created in consideration of a case where the needle 18 is erroneously cut.

Returning to FIG. 23, step S235 will be described.

Step S235: The control computer 22 moves the needle 18 and the stage 13 and moves the tip of the needle 18 to a center of the field of view.

Step S236: The control computer 22 stops the movement of the needle 18 after moving the tip of the needle 18 to the center of the field of view.

Step S237: The control computer 22 acquires image data including the tip of the needle 18 by irradiation with the focused ion beam. The acquired image including the needle 18 is transmitted to the image processing computer 30.

Step S238: The control computer 22 determines whether the needle 18 needs to be cleaned. The determination image acquisition unit 303 acquires an image from the image processing computer 30 as a determination image. The determination unit 304 determines whether a foreign matter adheres to the tip of the needle 18 based on the machine learning model M. When it is determined that no foreign matter adheres to the tip of the needle 18, it is determined that the needle 18 does not need to be cleaned (No), and the process proceeds to step S239. In the machine learning model M used here, since the learning images of the needle 18 described with reference to FIGS. 24 and 25 are learned, the shape of the needle 18 can be accurately determined. Therefore, it is possible to accurately determine whether a foreign matter adheres to the tip of the needle 18.

When it is determined that a foreign matter adheres to the tip of the needle 18, it is determined that the needle 18 needs to be cleaned (Yes), and the process proceeds to step S240. At this time, a position of the foreign matter adhering to the tip of the needle 18 included in the determination image acquired by the determination image acquisition unit 303 is determined as the position of the object. The determination unit 304 outputs position information indicating the determined position of the needle 18 to the control computer 22. The machine learning model M used here includes a learning model for foreign matter region determination described below and a learning model for needle cleaning necessity determination.

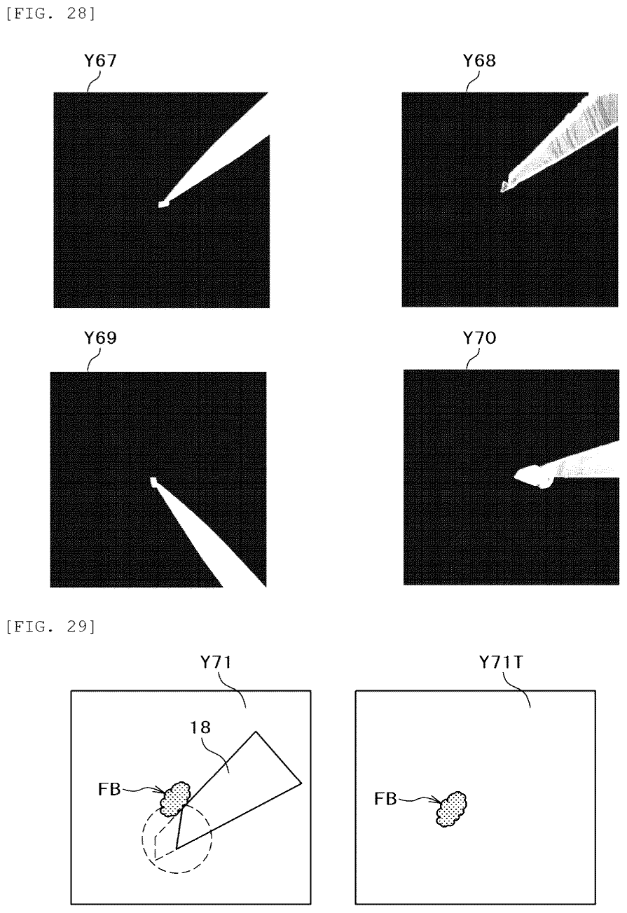

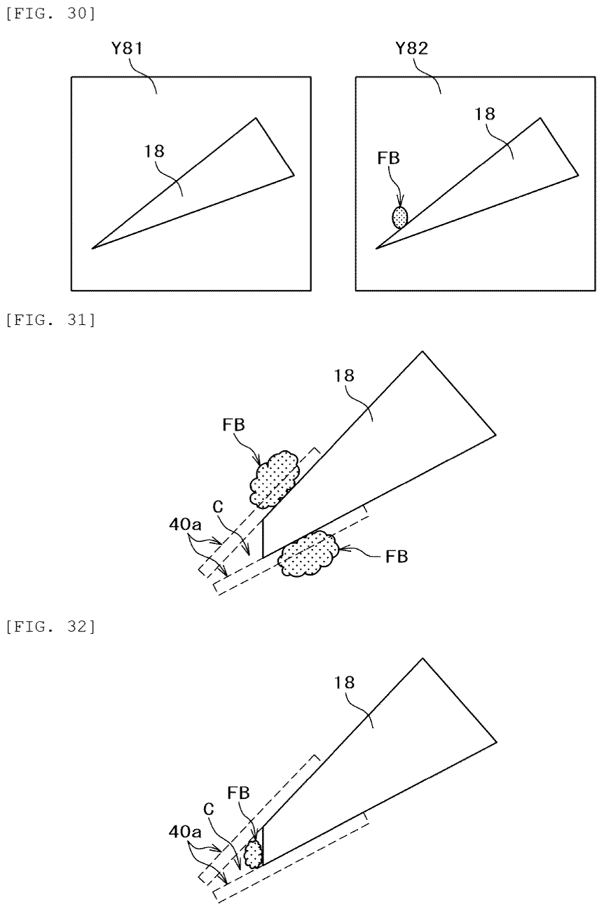

Here, an example of learning images of the needle 18 used to generate the machine learning model M used to determine the necessity of cleaning will be described with reference to FIGS. 26, 27, 28, 29, and 30. FIGS. 26 to 29 are diagrams illustrating an example of a learning model for the foreign matter region determination. FIG. 26 is a diagram illustrating an example of original images of a needle to which a foreign matter adheres. FIG. 27 is a diagram illustrating an example of a teacher image showing a region of foreign matters in the original image in FIG. 26. FIG. 28 is a diagram illustrating an example of original images in which contrast, an angle, magnification, a position, and the like of the needle are changed. FIG. 29 is a diagram illustrating an example of one set of learning data of an original image in which foreign matter adheres to a tip portion of a needle whose tip thickness has been changed by the cleaning and a teacher image thereof. FIG. 30 is a diagram illustrating an example of a learning model for needle cleaning necessity determination.

As illustrated in FIG. 26, in original images Y61 to Y66 of the needle 18, the foreign matter FB adheres to a tip portion of the needle 18. FIG. 27 illustrates teacher images Y61T to Y66T indicating regions of the foreign matter FB in the original images Y61 to Y66. In the generation of the machine learning model M, the original image Y61 and the teacher image Y61T are used as a pair of learning data. Similarly, the original image Y62 and the teacher image Y62T, the original image Y63 and the teacher image Y63T, the original image Y64 and the teacher image Y64T, the original image Y65 and the teacher image Y65T, and the original image Y66 and the teacher image Y66T are used as a pair of learning data.

The learning data used to generate the machine learning model M includes original images and teacher images. The teacher image includes information indicating only a foreign matter portion of the original image. The teacher image is created by designating, for example, which portion is a region of foreign matters in the original image. By capturing a plurality of pieces of learning data into the machine learning model M, it is possible to determine a region of foreign matters from an original image of a needle to which a foreign matter adheres. It is also possible to add learning data to the machine learning model M later based on image data of the tip of the needle 18 acquired during use of the charged particle beam device 10.

FIG. 28 illustrates original image Y67 to Y70 in which contrast, an angle, magnification, a position, and the like of the needle 18 are changed. As an original image used for image learning data, it is preferable to use an image in which the tip shape of the needle 18, the way of adhesion of a foreign matter, the contrast, the magnification, an angle and a position of the needle 18, and the like are changed as illustrated in FIG. 28. By creating a learning model that captures images of various conditions, it is possible to determine a region of foreign matters with high robustness.

FIG. 29 illustrates an original image Y71 in which the foreign matter FB adheres to the tip portion of the needle 18 whose tip thickness has been changed by the cleaning, and a teacher image Y71T thereof. In order to accurately determine the region of the foreign matter even if the tip shape of the needle 18 loses a sharp shape due to repeated use, it is preferable to prepare a machine learning model for determining a region of another foreign matter including a learning set of the original image (Y71) in a state where the tip of the needle is scraped and the teacher image (Y71T) of the foreign matter adhering thereto. By selectively using the machine learning model according to the frequency of use of needle cleaning, it is possible to stably determine the region of the foreign matter.

FIG. 30 illustrates an example of a machine learning model for needle cleaning necessity determination. The learning model for needle cleaning necessity determination includes an image Y81 illustrating an example of the needle 18 that does not require cleaning and an image Y82 illustrating an example of the needle 18 that requires cleaning. For the determination of the necessity of needle cleaning, a machine learning model for the foreign matter region determination (FIGS. 26 to 29) may be used, or a machine learning model for needle cleaning determination (FIG. 30) may be used.

When an area (the number of pixels) of a region determined as the region of foreign matters is smaller than a certain value in step S238, it is determined that “there is no influence on micro-sampling”, and the cleaning process (steps S240 and S241) to be described later can be skipped. This determination can be performed by applying the determination result of the determination model (FIGS. 26, 27, and the like) of the region of foreign matters.

Returning to FIG. 23, step S239 will be described.

Step S239: The control of the control computer 22 proceeds to step S50 for processing a next sample piece Q.

Step S240: The control computer 22 determines a cleaning region of the needle 18. The control computer 22 sets a processing frame (also referred to as a processing region) for performing etching processing using the focused ion beam, based on the position information indicating the position of the foreign matter adhering to the tip of the needle 18 determined by the image processing computer 30. The setting of the processing frame will be described later.

Step S241: The control computer 22 etches the inside of the set processing frame by the focused ion beam to remove foreign matters such as deposits such as a deposited film or residues of the sample piece adhering to the needle 18, and shapes the tip of the needle 18 into a desired shape by the focused ion beam. Thereafter, the control of the control computer 22 proceeds to step S237 and performs the subsequent steps.

As described above, the control computer 22 controls the charged particle beam irradiation optical system to shape the shape of the needle 18, based on the determination of the machine learning model M, using the machine learning model M in which information including an image of the needle is learned. Accordingly, the control computer 22 can remove foreign matters such as deposits such as a deposited film and residues of the sample piece adhering to the needle 18, and shape the tip of the needle 18 into a desired shape by the focused ion beam.

When an abnormality occurs in a foreign matter region determination process in the image processing computer 30, the control computer 22 initializes position coordinates of the needle 18, moves the needle 18 to an initial position, and then moves the needle 18 to a place where there is no structure on a background of the needle 18. Further, even after the position coordinates of the needle 18 are initialized, when an abnormality occurs in the foreign matter region determination process in the image processing computer 30, the control computer 22 determines that an abnormality such as deformation occurs in the shape of the needle 18, displays a warning message on a screen, and ends the automatic sample sampling. Alternatively, an automatic replacement sequence of the needle 18 is performed.

The control computer 22 may perform the needle trimming process (step S230) every time automatic sample sampling is performed. By periodically executing the needle trimming process (step S230), the automatic sample sampling process can be stabilized. In particular, the fixing strength between the needle 18 and the sample piece Q can be maintained by removing deposits such as the deposited film DM2 and the residue of the sample piece Q adhering to the distal tip portion of the needle 18 close to the sample piece Q to expose the distal tip portion of the needle 18. By executing the needle trimming process (step S230), the sampling of the sample piece Q can be performed by repeatedly using the needle 18 without replacing the needle 18, and thus a plurality of sample pieces Q can be continuously sampled using the same needle 18.

The timing of performing the needle trimming process (S230) is not limited to the timing when the automatic sample sampling is performed, and the needle trimming process can be performed at any timing such as a first time when the needle 18 is replaced.

Next, the setting of the processing frame will be described.

### (Setting of Processing Frame by Artificial Intelligence (AI))

As described in the needle trimming process (S230), the image processing computer 30 performs image recognition of the position of the tip of the needle 18 (step S238) using the image data (step S237) generated by irradiation with the focused ion beam, and then determines a region of foreign matters adhering to the needle 18 (step S240). The region of foreign matters determined by the image processing computer 30 is transmitted to the control computer 22, and the control computer 22 sets a processing frame (processing region) of the focused ion beam corresponding to the region of foreign matters and performs sharpening processing on the tip of the needle 18 (step S241). Here, the sharpening processing can be regarded as including a removal process of removing foreign matters from the tip of the needle 18 and a shaping process of shaping the tip of the needle 18 into a desired shape.

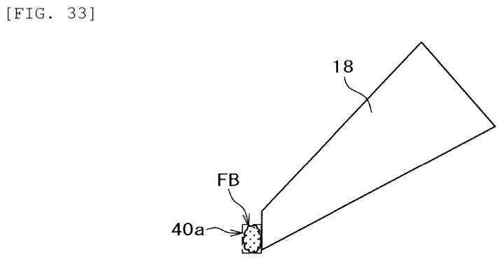

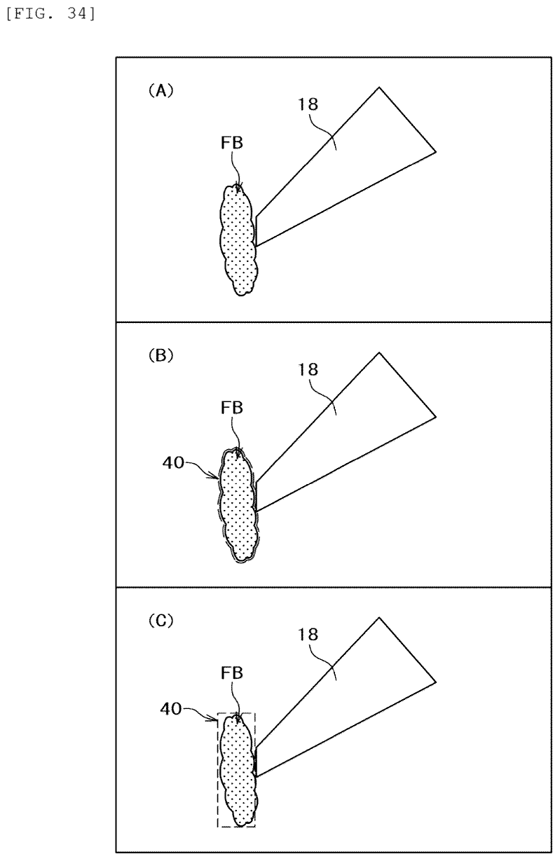

The processing frame of the focused ion beam will be described with reference to FIGS. 31 to 34. FIG. 31 is a diagram illustrating an example of a processing frame according to a comparative example. FIG. 32 is a diagram illustrating a problem of the processing frame according to the comparative example. FIG. 33 is a diagram illustrating an example of a processing frame according to the embodiment. FIG. 34 is a diagram illustrating a setting example of the processing frame according to the embodiment.

FIG. 31 illustrates a tip of the needle 18 set in processing frames 40a according to a comparative example. The processing frames 40a are rectangular processing frames in which an ideal tip position C is assumed by linearly approximating from the tip to a portion on a base end or the like of the needle 18. In this example, the processing frames 40a are set on an upper side and a lower side of the needle 18. By performing etching processing using the focused ion beam in a range of the processing frames 40a (range inside the frames), foreign matters FB adhering to the upper side and the lower side of the needle 18 can be removed.

FIG. 32 illustrates a case where the foreign matter FB adheres to a tip portion of the needle 18. In this example, the foreign matter FB is located between the processing frames 40a set on the upper side and the lower side of the needle 18. Therefore, even when the etching processing is performed using the focused ion beam, there is a problem that the foreign matter FB cannot be removed since the foreign matter FB is not located within the range of the processing frames 40a (range inside the frames). That is, the foreign matter FB adhering to a distal tip of the needle 18 cannot be removed.

FIG. 33 illustrates an example of a processing frame 40 according to the embodiment. As illustrated in FIG. 33, in this example, the processing frame 40 is a rectangular processing frame set to surround the periphery of the foreign matter FB. Therefore, when the etching processing is performed using the focused ion beam, since the foreign matter FB is located within a range of the processing frame 40 (range inside the frame), the foreign matter FB can be removed unlike the case of the processing frames 40a illustrated in FIG. 32. That is, the foreign matter FB adhering to the distal tip of the needle 18 can be removed.

FIG. 34 illustrates setting examples of the processing frame according to the embodiment, in which (A) illustrates an example of an image of the needle 18 in which the foreign matter FB adheres to the tip portion, (B) illustrates an example in which the processing frame 40 having the same shape as a shape of the foreign matter FB is set around the foreign matter FB, and (C) illustrates an example in which a rectangular processing frame 40 is set around the foreign matter FB to surround the foreign matter FB. As described above, the shape of the processing frame 40 can be set to any shape and can be selected in accordance with the shape of the foreign matter.

The shape of the processing frame 40 set by the control computer 22 is different from the shape of the rectangular processing frame 40a in which the ideal tip position C is assumed by linearly approximating from the tip to a portion on the base end or the like of the needle 18 as illustrated in FIGS. 31 and 32, and the processing frame 40 is the processing frame 40 set in a region to which a foreign matter adheres as illustrated in FIGS. 33 and 34.

Therefore, the processing frame 40 can be installed even for the foreign matter FB adhering to a gap between the ideal tip position C and the actual tip of the needle 18. Therefore, the foreign matter FB adhering to the gap between the ideal tip position C and the actual tip of the needle 18 can be removed. By the foreign matter removal processing and the sharpening processing of the needle 18, the tip of the needle 18 can be regenerated until a main body to which no foreign matter adheres is exposed. Accordingly, it is possible to process the needle 18 into a shape optimal for transferring the sample piece Q.

For example, when the image processing computer 30 determines that there is no region corresponding to the foreign matter FB in the image of the needle 18 in step S238, the control computer 22 does not set the processing frame 40 by the focused ion beam, and the needle cleaning process (S240, S241) is skipped.

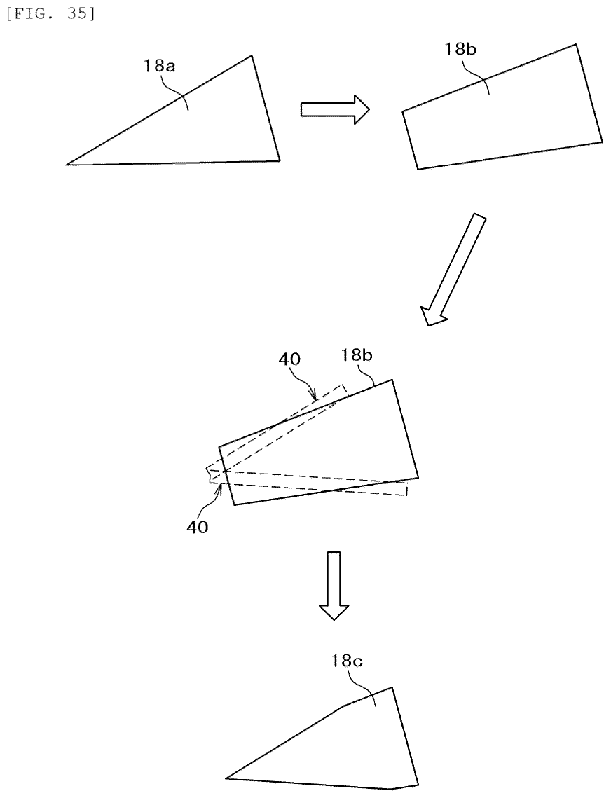

Further, for example, when the image processing computer 30 cannot specify the shape of the needle 18 in the image of the needle 18 and determines that the needle 18 is deformed in step S238, the control computer 22 does not set the processing frame 40 by the focused ion beam, and the needle cleaning process (S240, S241) is skipped. Alternatively, after that, there is a case in which a process of automatically replacing a needle is executed, or a case in which, when it is determined that the needle 18 is deformed, the needle 18 may be shaped in order to correct the deformation of the needle 18. By shaping the deformed needle 18, a needle having a shape optimal for transferring a sample piece is obtained. FIG. 35 is a diagram illustrating shaping of the needle 18. As illustrated in FIG. 35, an initial needle 18a may be deformed like a needle 18b after use or after being largely scraped for some reason. That is, a tip of the initial needle 18a is pointed at an acute angle like a corner of a triangle, but a tip of the deformed needle 18b has a rectangular shape. Therefore, the shape of the needle 18a is recognized by artificial intelligence (AI), and the control computer 22 places the processing frames 40 (here, two processing frames 40) on the needle 18b and re-forms the shape of the needle by sharpening processing. That is, the control computer 22 causes the charged particle beam irradiation optical system 14 to radiate the charged particle beam based on the determination of the machine learning model, and shapes the needle 18b based on the processing frame 40. By shaping the tip of the needle 18b, for example, a needle 18c having a sharpened tip is obtained. Accordingly, the needle 18c having a shape optimal for transferring a sample piece can be obtained. In FIG. 35, a case where the tip shape of the needle is pointed at an acute angle like a corner of a triangle has been described, and it is also possible to install the processing frame 40 so that the shape of the tip of the needle is formed in a prismatic shape. Even when the tip of the needle has a prismatic shape, it can be said that the shape is optimal for transferring the sample piece.

The image processing computer 30 also recognizes a size of the foreign matter FB adhering to the needle 18, and transmits a determination result of the size of the foreign matter FB adhering to the control computer 22. The control computer 22 controls the focused ion beam irradiation optical system 14, which is an irradiation unit of the focused ion beam, based on information on a size of the foreign matter received from the image processing computer 30, and changes a beam condition of the focused ion beam with which the foreign matter FB is irradiated. That is, a current amount of the focused ion beam with which the foreign matter FB is irradiated may be changed. A processing time can be shortened by removing the large foreign matter FB with a large amount of focused ion beam. The foreign matter FB can be accurately removed by removing the small foreign matter FB with a small amount of focused ion beam having small aberration.

When the control computer 22 installs the processing frame 40 in a region determined as the region of the foreign matter FB by the image processing computer 30, the coordinate information of the region of the foreign matter FB may be used, or the processing frame 40 may be installed based on an image of the region determined as the region of the foreign matter FB.

The control computer 22 rotates the needle 18 around a central axis by a rotation mechanism of the needle driving mechanism 19, similarly performs etching processing at a plurality of different specific rotation positions, and shapes the needle 18 into a desired shape. The operator can select whether to perform the etching processing at a plurality of different specific rotation positions of the needle 18 by the rotation mechanism of the needle driving mechanism 19.

The image processing computer 30 may use a conventional method of detecting an edge of the needle 18 in addition to the processing frame 40 installed by the control computer 22 for the region determined as the region of the foreign matter FB.

When an area of the region determined as the region of the foreign matter FB is smaller than a specified value, the image processing computer 30 can also select to skip the needle cleaning step (S240, S241).

Further, whether the image processing computer 30 performs the cleaning processing of the region determined as the region of the foreign matter FB can also be selected by the operator depending on a type and importance of a sample to be sampled next.

Since the shape of the needle 18 gradually changes through the processes of bonding and cutting a sample, the learning model can be selected according to the number of times of use (see FIG. 29).

The end of the needle cleaning processing may be determined by a processing time, or may be determined again by the artificial intelligence AI using the machine learning model M. In a case where the determination is performed by the artificial intelligence AI, in a case where the region of the foreign matter FB is not determined or the region determined as the region of the foreign matter FB is smaller than a specified size, the needle trimming process (step S230) is ended. Alternatively, a learning model of the needle 18 having an ideal shape without the foreign matter FB may be prepared for the end determination (see Y81 in FIG. 30). Further, the determination method using the artificial intelligence AI and a determination method using a learning model of the needle 18 having an ideal shape without the foreign matter FB may be used in combination.

In a case where the cleaning of the needle 18 to which the foreign matter FB adheres is successful, in order to use the image data as training data, the image data may be taken into the image processing computer 30 and self-learning may be performed. At this time, whether the sampling by the needle 18 after the cleaning is successful is added to a criterion as to whether the image data can be adopted as training data.

Further, a learning model including self-learned training data can be used as a learning model of another device.

By matching the tip shape of the needle 18 with a predetermined ideal shape set in advance, the computer 22 can easily recognize the needle 18 by pattern matching when driving the needle 18 in a three-dimensional space, and can accurately detect a position of the needle 18 in the three-dimensional space.

### (Modifications)

In the description of the above embodiment, the technique of performing control using the machine learning model M in the initial setting process, the sample piece pickup process, the sample piece mounting process, and the needle trimming process has been described, but the invention is not limited thereto. By performing control using the machine learning model M at least in the needle trimming process, it is possible to provide a charged particle beam device capable of removing the foreign matter FB adhering to the distal tip portion of the needle 18.

In the present embodiment, an example in which the learning data is a set of the learning image and information indicating the position of the object in the learning image has been described, but the invention is not limited thereto. In addition to the learning image, the learning data may include parameter information that is information indicating the type of the sample, a scan parameter (such as an acceleration voltage of the focused ion beam irradiation optical system 14 and the electron beam irradiation optical system 15), the number of times of use after the cleaning of the needle 18 is performed, whether a foreign matter is attached to the tip of the needle 18, and the like.

In this case, the machine learning model M is generated by executing machine learning based on the learning image and the parameter information. The determination unit 304 acquires parameter information in addition to image data of the SIM image and the SEM image from the control computer 22, and determines a position of the object in the image based on the image data, the parameter information, and the machine learning model M.

The parameter information may further include the direction information described above. When the direction information is included in the learning data, since a relation between an object and a direction in which the object is viewed (direction relative to the sample stage 12) is learned to generate the machine learning model M, the determination unit 304 does not need to use the direction information for determining a position of the object.

As described above, a computer (the control computer 22 in the present embodiment) controls a position of a second object (the columnar portion 44, the needle 18, and the sample piece Q in the present embodiment) based on a result obtained by the image processing computer 30 determining the position of the second object (the columnar portion 44, the needle 18, and the sample piece Q in the present embodiment) based on a model of machine learning (the machine learning model M in the present embodiment) and second information including a second image (the SIM image or the SEM image of the columnar portion 44, the needle 18, and the sample piece Q in the present embodiment). The image processing computer 30 and the control computer 22 may be integrally provided in the charged particle beam device 10.

Although the invention made by the present inventor has been specifically described above based on the embodiments, it is needless to say that the invention is not limited to the above-described embodiments and examples, and various modifications can be made.

### REFERENCE SIGNS LIST

10: charged particle beam device
18: needle
22: control computer
30: image processing computer
M: machine learning model
FB: foreign matter

1.-11. (canceled)

12. A charged particle beam device configured to repeatedly perform transferring a sample piece using a needle and cleaning the needle as necessary, the charged particle beam device comprising:
a charged particle beam irradiation optical system configured to perform radiation of a charged particle beam;
a sample stage configured to mount and move a sample;
a sample piece transferring unit including the needle configured to hold and transfer the sample piece separated and extracted from the sample and a needle driving mechanism configured to drive the needle;
a holder fixing base configured to hold a sample piece holder to which the sample piece is transferred;
a machine learning model in which information is learned, the information including an image in which a foreign matter adheres to the needle and, within the image, an image of a foreign matter part; and
a computer configured to determine a region of the foreign matter adhering to the needle based on determination of the machine learning model, irradiate the region with the charged particle beam, and control the charged particle beam irradiation optical system to process the foreign matter, wherein
a thickness of the tip of the needle is changed by the cleaning, and
the computer uses determination of another machine learning model in which information is learned according to frequency of the cleaning, the information including an image in which a foreign matter adheres to the needle of which the thickness of the tip is changed and, within the image, an image of a foreign matter part.

13. The charged particle beam device according to claim 12, wherein
the image of the needle learned in the machine learning model includes an image indicating a shape of the needle.

14. The charged particle beam device according to claim 12, wherein
the computer skips the radiation of the charged particle beam when it is determined that there is no region of the foreign matter adhering to the needle based on the determination of the machine learning model.

15. The charged particle beam device according to claim 14, wherein
the computer skips the radiation of the charged particle beam when an area of a region determined as the region of the foreign matter adhering to the needle is smaller than a predetermined value based on the determination of the machine learning model.

16. The charged particle beam device according to claim 12, wherein
the computer changes a beam condition of the charged particle beam based on an area of a region determined as the region of the foreign matter adhering to the needle based on the determination of the machine learning model.

17. The charged particle beam device according to claim 12, wherein
when it is determined that a shape of the needle is not be specified and the needle is deformed, based on the determination of the machine learning model, the computer skips the radiation of the charged particle beam or performs a process of replacing the needle without setting the processing region.

18. The charged particle beam device according to claim 12, further comprising:
a process of extracting the sample piece from the sample using the needle and transferring the sample piece to the sample piece holder;
a process of moving the needle to an irradiation position of the charged particle beam;
a process of irradiating the needle with the charged particle beam and acquiring an image;
a process of processing the image using the machine learning model and determining a processing region where the foreign matter adhering to the needle is to be removed; and
a process of radiating the charged particle beam and removing the foreign matter adhering to the needle in the processing region.
